(19) United States
(12) Patent Application Publication
(10) Pub. No.: US 2007/0178644 A1
(43) Pub. Date: Aug. 2, 2007

(54) Semiconductor device having an insulating layer and method of fabricating the same

(75) Inventors: Ja-eung Koo, Suwon-si (KR); Il-young Yoon, Hwaseong-si (KR); Jae-ouk Choo, Yongin-si (KR); Yong-kuk Jeong, Suwon-si (KR); Seo-woo Nam, Yongin-si (KR); Hong-jae Shin, Seoul (KR)

Correspondence Address: HARNESS, DICKEY & PIERCE, P.L.C., P.O. BOX 8910, RESTON, VA, 20195, US

(73) Assignee: Samsung Electronics Co. Ltd.

(21) Appl. No.: 11/698,070

(22) Filed: Jan. 26, 2007

(30) Foreign Application Priority Data
Jan. 27, 2006 (KR) 10-2006-0008986

(51) Int. Cl. H01L 21/336

(52) U.S. Cl. 438/261

(57) ABSTRACT

A semiconductor device having a dielectric or an insulating layer with decreased (or minimal) erosion properties when performing metal Chemical Mechanical Polishing (CMP) and a method of fabricating the same are provided. The semiconductor device may include gate electrodes formed on a substrate. A first interlayer oxide layer may be formed on the substrate and between the gate electrodes. A second interlayer oxide layer, which is harder than the first interlayer oxide layer, may be formed on the first interlayer oxide layer. A plug electrode may be formed through the second interlayer oxide layer and the first interlayer oxide layer.

### PRIORITY STATEMENT

This application claims the benefit of priority under 35 U.S.C. §119 from Korean Patent Application No. 10-2006-0008986, filed on Jan. 27, 2006, in the Korean Intellectual Property Office, the disclosure of which is incorporated herein in its entirety by reference.

### BACKGROUND

1. Field

Example embodiments relate to a semiconductor device and a method of fabricating the same. Other example embodiments relate to a semiconductor device having a dielectric or an insulating layer with decreased (or minimal) erosion properties when performing metal Chemical Mechanical Polishing (CMP) and a method of fabricating the same.

2. Description of the Related Art

Higher performance and higher integration in semiconductor devices require interconnects having a multi-layered structure. As such, conductive layer stacking, conductive layer patterning, insulating layer stacking on the conductive layer and insulating layer patterning must be repeated in order to form the interconnects having the multi-layered structure. The respective layers have a topography that becomes more severe as more layers are stacked thereon. The topography degrades a focus depth during exposure resulting in a poor pattern.

Chemical Mechanical Polishing (CMP) has been developed and used to planarize the stacked layers. CMP may be classified as an oxide CMP process or a metal CMP process. During the metal CMP process, a metal layer filled in a contact hole is stacked on an insulating layer or a dielectric having the contact hole therein. The metal layer is polished until the insulating layer is exposed. The metal layer is overly polished over a region having more closely formed contact holes rather than a region having more loosely formed contact holes in order that dishing of the metal layer may occur. The insulating layer adjacent to the more closely formed contact holes may erode. The erosion of the insulating layer may cause an error during photolithography and subsequent etching processes.

The conventional art acknowledges a method for improving oxide erosion of a tungsten CMP operation. According to the conventional art, an oxide layer is stacked on a substrate and subjected to CMP. A silicon nitride layer is stacked on the polished oxide layer. A contact hole is formed through the nitride layer and the oxide layer. A metal layer, which is filled in the contact hole, is formed on the nitride layer. The metal layer is subjected to CMP. Because the nitride layer functions as a polishing stop layer during the metal CMP, erosion of the insulating layer may not occur.

If the silicon nitride is used as the polishing stop layer, then a substantial amount of residue may be produced when forming the contact hole. The residue may accumulate in the contact hole, resulting in the contact hole having a poor opening.

### SUMMARY

Example embodiments relate to a semiconductor device and a method of fabricating the same. Other example embodiments relate to a semiconductor device having a dielectric or an insulating layer with decreased (or minimal) erosion properties when performing metal Chemical Mechanical Polishing (CMP) and a method of fabricating the same.

Example embodiments provide a semiconductor device that prevents or reduces the likelihood of forming a contact hole with a poor opening and method of fabricating the same.

According to example embodiments, there is provided a semiconductor device including gate electrodes disposed (or formed) on a substrate. A first interlayer oxide layer may be disposed (or formed) on the substrate in (or over) a region where gate electrodes will be formed. The first interlayer oxide layer may be formed such that the first interlayer oxide layer fills a space between the gate electrodes after the gate electrodes are formed on the substrate. A second interlayer oxide layer may be disposed (or formed) on the first interlayer oxide layer. The second interlayer oxide layer may be harder than the first interlayer oxide layer. A plug electrode may be formed through (or penetrating) the second interlayer oxide layer and the first interlayer oxide layer.

According to example embodiments, there is provided a method of fabricating a semiconductor device. A first interlayer oxide layer may be formed on a substrate in (or over) a region where gate electrodes will be formed. The first interlayer oxide layer may be formed such that the first interlayer oxide layer fills a space between the gate electrodes after the gate electrodes are formed on the substrate. A second interlayer oxide layer may be formed on the first interlayer oxide layer. The second interlayer oxide layer may be harder than the first interlayer oxide layer. A contact hole may penetrate (or be formed) through the second interlayer oxide layer and the first interlayer oxide layer. A first interconnect conductive layer may be formed on the second interlayer oxide layer forming a portion of the contact hole. The first interconnect conductive layer may be subjected to chemical-mechanical polishing (CMP) to form a plug electrode. The second interlayer oxide layer (e.g., an oxide layer with a lower removal or etch rate with respect to the CMP) may be exposed when performing CMP on the first interconnect conductive layer. Erosion of the second interlayer oxide layer around the plug electrode may significantly decrease.

The first interlayer oxide layer may be a High Aspect Ratio Process (HARP) oxide layer. Performance of a transistor under the HARP oxide layer may increase.

In other example embodiments, the first interlayer oxide layer may be a low dielectric constant film. A parasitic capacitance between the gate electrodes may decrease. The parasitic capacitance between interconnects, which have the low dielectric constant film interposed between, may also decrease. The low dielectric constant film may be formed of SiOC.

The first interlayer oxide layer may be subjected to CMP prior to forming the second interlayer oxide layer. The second interlayer oxide layer may be formed of a material selected from a group consisting of Tetra Ethyl Ortho Silicate (TEOS), Undoped Silica Glass (USG), Fluorine-doped Silicate Glass (FSG) and a combination thereof.

The first interconnect conductive layer may be formed of tungsten. As such, the plug electrode may be a tungsten plug electrode.

### BRIEF DESCRIPTION OF THE DRAWINGS

Example embodiments will be more clearly understood from the following detailed description taken in conjunction with the accompanying drawings. FIGS. 1A-1F represent non-limiting, example embodiments as described herein.

FIGS. 1A through 1F are diagrams illustrating sectional views of a method of fabricating a semiconductor device according to example embodiments.

### DETAILED DESCRIPTION OF EXAMPLE EMBODIMENTS

Various example embodiments will now be described more fully with reference to the accompanying drawings in which some example embodiments are shown. In the drawings, the thicknesses of layers and regions may be exaggerated for clarity.

Detailed illustrative embodiments are disclosed herein. However, specific structural and functional details disclosed herein are merely representative for purposes of describing example embodiments. This invention may, however, may be embodied in many alternate forms and should not be construed as limited to only the example embodiments set forth herein.

Accordingly, while the example embodiments are capable of various modifications and alternative forms, embodiments thereof are shown by way of example in the drawings and will herein be described in detail. It should be understood, however, that there is no intent to limit example embodiments to the particular forms disclosed, but on the contrary, the example embodiments are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the example embodiments. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of the example embodiments.

Spatially relative terms, such as “beneath,” “below,” “lower,” “above,” “upper” and the like, may be used herein for ease of description to describe one element or a relationship between a feature and another element or feature as illustrated in the figures. It will be understood that the spatially relative terms are intended to encompass different orientations of the device in use or operation in addition to the orientation depicted in the Figures. For example, if the device in the figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

Example embodiments are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope.

It should also be noted that in some alternative implementations, the functions/acts noted may occur out of the order noted in the figures. For example, two figures shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments, various aspects will be described in detail with reference to the attached drawings. However, the present invention is not limited to the example embodiments described.

Example embodiments relate to a semiconductor device and a method of fabricating the same. Other example embodiments relate to a semiconductor device having a dielectric or an insulating layer with decreased (or minimal) erosion properties when performing metal Chemical Mechanical Polishing (CMP) and a method of fabricating the same.

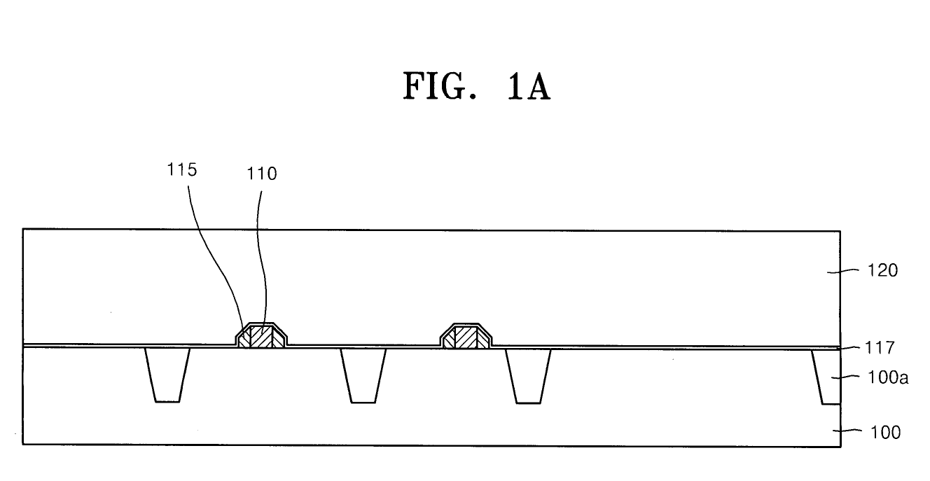

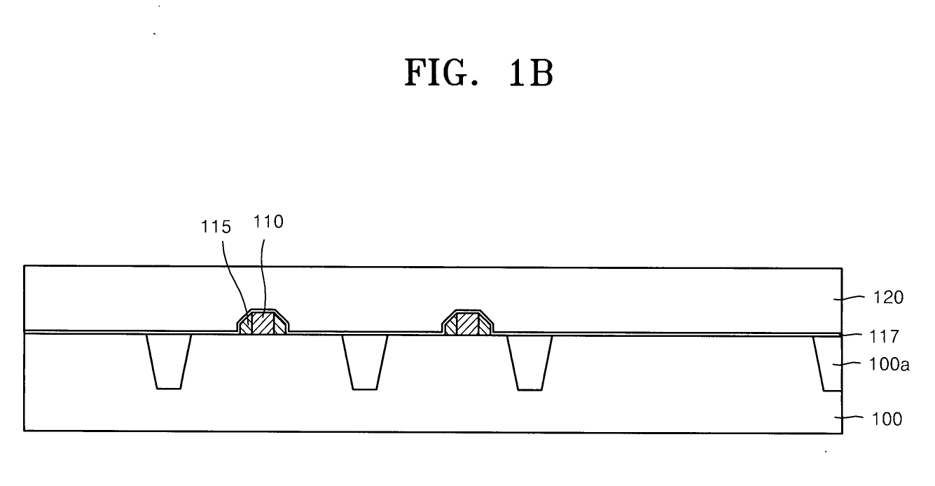

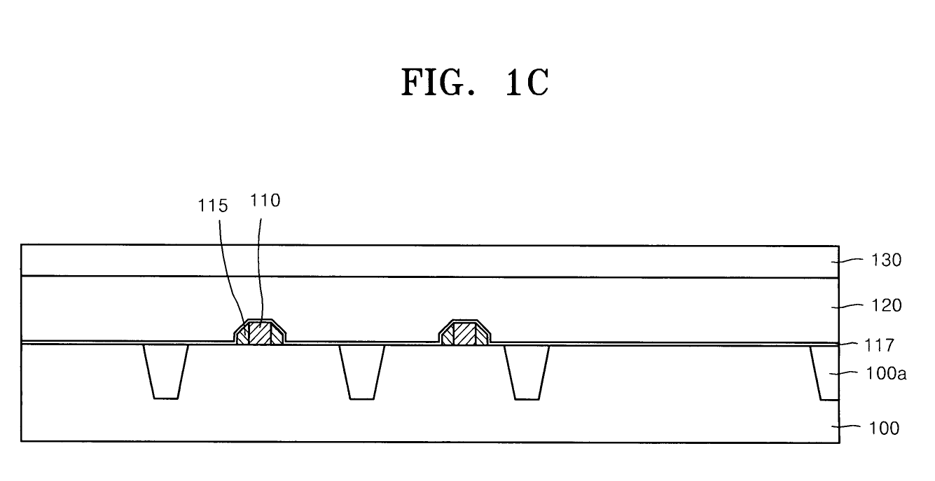

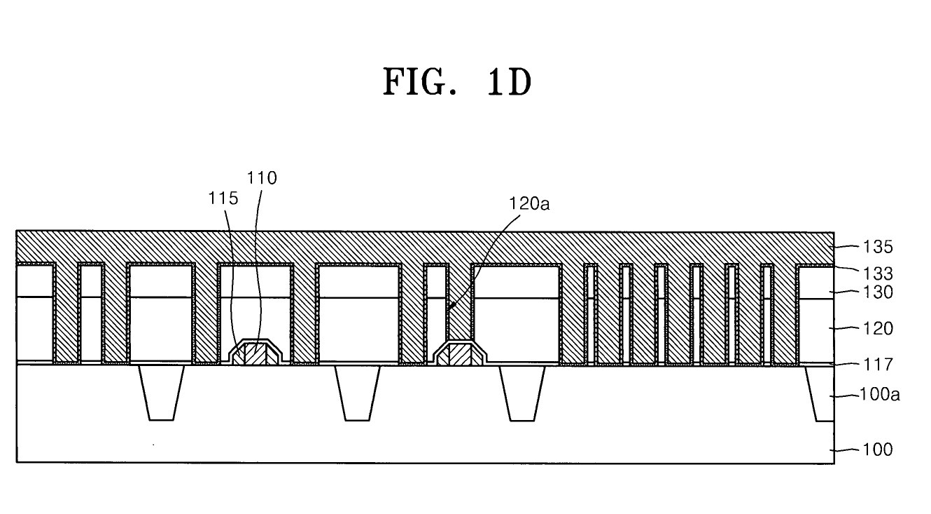

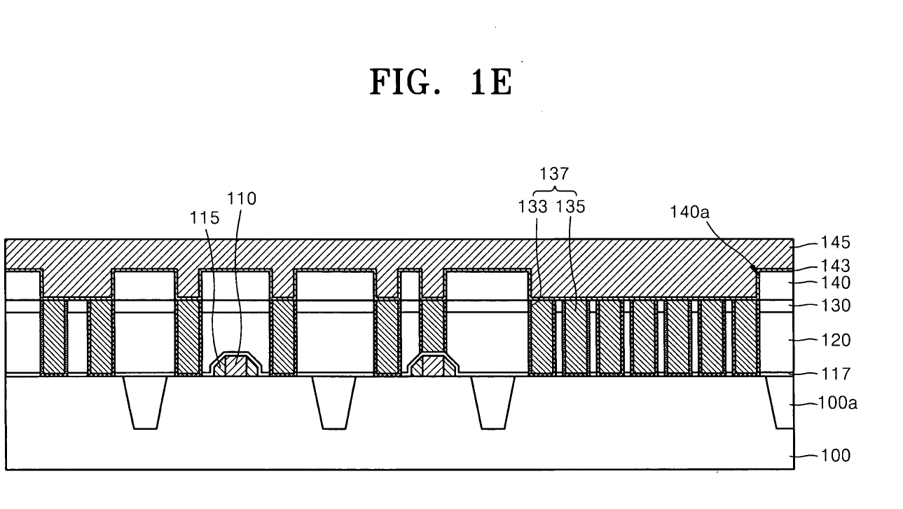

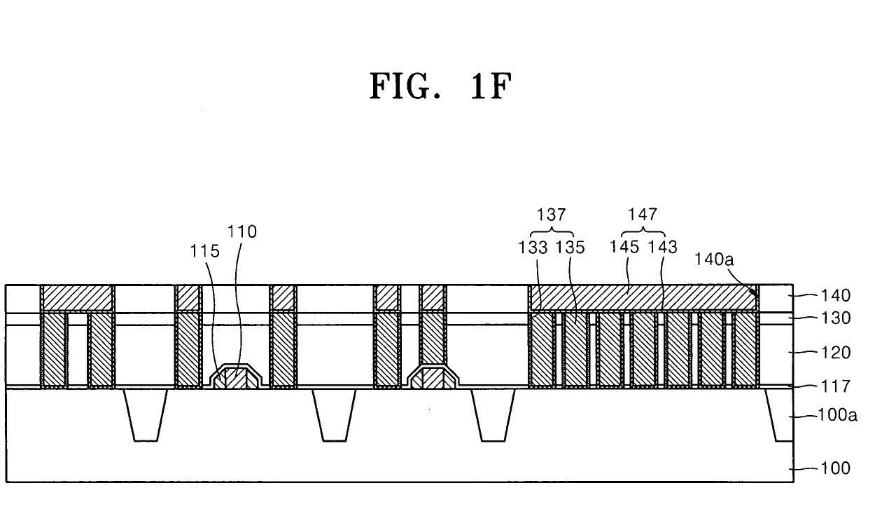

FIGS. 1A through 1F are diagrams illustrating sectional views of a method of fabricating a semiconductor device according to example embodiments.

Referring to FIG. 1A, a substrate 100 is prepared. A device isolating structure 100a is formed in the substrate 100 to define an active region. The device isolating structure 100a may be formed by trench isolation (as illustrated in the drawing) or Local Oxidation of Silicon (LOCOS). The device isolating structure 100a may be formed by other methods well-known in the art.

Gate electrodes 110 are formed on the substrate 100. A gate insulating layer (not shown) may be formed on the substrate 100 prior to forming the gate electrodes 110. The gate electrodes 110 may be formed by sequentially stacking and etching gate conductive layers (e.g., a gate polysilicon layer and a gate silicide layer).

A spacer insulating layer (not shown) is formed on the gate electrodes 110. The spacer insulating layer is anisotropically etched to form spacers 115 along sidewalls of the gate electrodes 110. The spacer insulating layer may be formed of SiNₓ or SiON.

Using the gate electrodes 110 and the spacers 115 as masks, an impurity may be doped in the substrate 100 to form source/drain regions (not shown). The source/drain regions may be formed on sides of the gate electrode 110. A channel region is defined under the gate electrode 110.

A first etch stop layer 117 is formed on the gate electrodes 110 and the substrate 100 exposed by the gate electrodes 110. The first etch stop layer 117 may be formed of SiNₓ or SiON selective to silicon oxide. The first etch stop layer 117 may have a thickness of between 300 Å-600 Å.

A first interlayer oxide layer 120 is formed on the first etch stop layer 117. The first interlayer oxide layer 120 is formed in (or over) a region where gate electrodes will be formed. The first interlayer oxide layer 120 is formed such that the first interlayer oxide layer 120 fills a space between the gate electrodes after the gate electrodes are formed on the substrate 100. The first interlayer oxide layer 120 may have a thickness of about 5000 Å.

The first interlayer oxide layer 120 may be a High Aspect Ratio Process (HARP) oxide layer. The HARP oxide layer is characterized by stacking an insulating material coated on a substrate at several stacking speeds. The insulating material may be slowly stacked to conformably cover steps and subsequently quickly stacked to fill the HARP oxide layer in the space between the gate electrodes 110 with no voids. A stress applied on the substrate 110 is controlled to increase performance of a transistor. A tensile force is applied to the channel region to increase a saturation current of the transistor.

In other example embodiments, the first interlayer oxide layer 120 may be a low dielectric constant film. The low dielectric constant film decreases a parasitic capacitance between the gate electrodes 110. The low dielectric constant film may also decrease the parasitic capacitance between interconnects wherein the low dielectric constant film is interposed between the interconnects. Decreasing the parasitic capacitance increases a data transfer speed of the interconnects. The low dielectric constant film may be a SiOC layer. The low dielectric constant film may have a dielectric constant lower than that of SiO₂.

The first interlayer oxide layer 120 is planarized using a CMP process.

Referring to FIG. 1B, the polished first interlayer oxide layer 120 may have a height of approximately 3000 Å from the substrate 100. A surface of the first interlayer oxide layer 120 may have scratches generated from performing the CMP process.

Referring to FIG. 1C, a second interlayer oxide layer 130 is formed on the polished first interlayer oxide layer 120. The scratches on the surface of the first interlayer oxide layer 120 may be filled. The second interlayer oxide layer 130 is harder than the first interlayer oxide layer 120. The second interlayer oxide layer 130 has a higher mechanical strength than the first interlayer oxide layer 120 in order that a removal or etch rate of the second interlayer oxide layer 130 by a subsequent CMP process is slower than that of the first interlayer oxide layer 120.

If the first interlayer oxide layer 120 is planarized, then the second interlayer oxide layer 130 has a planarized surface. The second interlayer oxide layer 130 may be formed of (e.g., Tetra Ethyl Ortho Silicate (TEOS), Undoped Silica Glass (USG), Fluorine-doped Silicate Glass (FSG) or a combination thereof). A thickness of the second interlayer oxide layer 130 may be approximately 1500 Å.

Referring to FIG. 1D, contact holes 120a are formed in the second interlayer oxide layer 130 and the first interlayer oxide layer 120. The contact holes 120a penetrate (or are formed through) the second interlayer oxide layer 130 and the first interlayer oxide layer 120. The first etch stop layer 117 is used as an etch end point when forming the contact holes 120a. The first etch stop layer 117 is exposed in the contact holes 120a. The exposed first etch stop layer 117 is etched to form the contact holes 120a exposing the substrate 100 or the gate electrodes 110.

A first barrier conductive layer 133 may be formed on an upper surface of the second interlayer oxide layer 130. The first barrier conductive layer 133 may be formed on the contact holes 120a. The first barrier conductive layer 133 may be formed of (e.g., Ti, Ta, TiN, TaN or a multiple layers thereof). The first barrier conductive layer 133 may be obtained (or formed) by sequentially stacking titanium (Ti) and titanium nitride (TiN). The first barrier conductive layer 133 may be formed to conformably coat the contact holes 120a.

A first interconnect conductive layer 135 is formed on the first barrier conductive layer 133. The first interconnect conductive layer 135 fills a space between the contact holes 120a. The first interconnect conductive layer 135 may be formed of tungsten.

Referring to FIG. 1E, the first interconnect conductive layer 135 and the first barrier conductive layer 133 are subjected to CMP until the second interlayer oxide layer 130 is exposed. The polished first interconnect conductive layer 135 and the first barrier conductive layer 133 form a plug electrode 137. The plug electrode 137 is formed through the second interlayer oxide layer 130 and the first interlayer oxide layer 120. The plug electrode 137 is connected to the substrate 100 or the gate electrode 110.

The second interlayer oxide layer 130 is harder than the first interlayer oxide layer 120. As such, the second interlayer oxide layer 130 has a lower removal rate during a metal CMP process. If the first interconnect conductive layer 135 and the first barrier conductive layer 133 are subjected to CMP, then no (or minimal) scratches may occur in the second interlayer oxide layer 130. The second interlayer oxide layer 130 according to example embodiments results in a decrease in erosion. The erosion of an area of the interlayer oxide layer adjacent to the plug electrode is significantly decreased in a region where the plug electrodes are more closely formed. As such, a surface of the completely polished second interlayer oxide layer 130 is substantially planarized.

An inter-metal dielectric 140 is formed on the plug electrode 137 and the second interlayer oxide layer 130 exposed around the plug electrode 137. A second etch stop layer (not shown) may be formed on the second interlayer oxide layer 130 prior to forming the inter-metal dielectric 140. The second etch stop layer may be formed of SiCN. The inter-metal dielectric 140 may be formed of SiCOH.

A groove 140a is formed in the inter-metal dielectric 140 and the second etch stop layer to expose the plug electrode 137. A second barrier conductive layer 143 and a second interconnect conductive layer 145 are sequentially stacked in the groove 140a. The second barrier conductive layer 143 may be formed of (e.g., titanium (Ti), tantalum (Ta), titanium nitride (TiN), tantalum nitride (TaN) or a multiple layer thereof). The second barrier conductive layer 143 may be obtained by sequentially stacking titanium (Ti) and titanium nitride (TiN). The second interconnect conductive layer 145 may be formed of copper (Cu).

Referring to FIG. 1F, the second interconnect layer 145 and the second barrier conductive layer 143 are polished until the inter-metal dielectric 140 is exposed. The polished second metal conductive layer 145 and the second barrier conductive layer 143 form an interconnect 147. The interconnect 147 is formed through the inter-metal dielectric 140 such that the interconnect 147 connects to the plug electrode 137.

As described above, if the surface of the second interlayer oxide layer 130 is nearly (or substantially) planarized, then the surface of the inter-metal dielectric 140 may be nearly (or substantially) planarized. If the second barrier conductive layer 143 and the second interconnect conductive layer 145 are stacked, then the surface of the second barrier conductive layer 143 on the inter-metal dielectric 140 and the surface of the second interconnect conductive layer 145 may be nearly (or substantially) planarized. See FIG. 1E.

Residues of the second interconnect conductive layer 145 or the second barrier conductive layer 143 may not be remain on the substrate 100 after completing the polishing of the second interconnect conductive layer 145 and the second barrier conductive layer 143. Experimental examples will now be described to assist understanding of the example embodiments.

### Fabrication Example

A gate electrode is formed on a substrate. A HARP oxide layer is stacked to a thickness of about 5000 Å on the gate electrode. The HARP oxide layer is subjected to CMP until a height of the HARP oxide layer is 3000 Å. A TEOS oxide layer is stacked to a thickness of 1500 Å on the polished HARP oxide layer. A contact hole is formed in the TEOS oxide layer and the HARP oxide layer. A tungsten layer, filling the contact hole, is stacked on the TEOS oxide layer to a thickness of 3000 Å. The tungsten layer is subjected to CMP until the TEOS layer is exposed.

### Comparison 1

A specimen is prepared similar to the above example except that a High Density Plasma (HDP)-CVD oxide layer is used instead of the HARP oxide layer.

### Comparison 2

A gate electrode is formed on a substrate. A HARP oxide layer is stacked on the gate electrode to a thickness of 6500 Å. The HARP oxide layer is subjected to CMP until the polished HARP oxide layer has a height of 4500 Å. A contact hole is formed in the polished HARP oxide layer. A tungsten layer, filling the contact hole, is stacked on the HARP oxide layer to a thickness of 3000 Å. The tungsten layer is subjected to CMP until the HARP layer is exposed.

### Influence Evaluation of Interlayer Oxide Layer upon Performance of the Transistor

Table 1, below, shows a saturation current of a transistor used with an interlayer oxide layer prepared according to Fabrication Example and Comparison 1. The saturation current was obtained when an off-current of the corresponding transistor was 7 nA/μm.

TABLE 1

| | | Saturation Current |
|---|---|---|
| | Type of Interlayer Oxide Layer | (Iₛₐₜ = 7 nA/μm) |
| Fabrication | HARP oxide layer/ | 600 μA/μm |
| Example | TEOS oxide layer | |
| Comparison 1 | HDP-CVD oxide layer/ | 540 μA/μm |
| | TEOS oxide layer | |

Referring to Table 1, if a HARP oxide layer is used as the first interlayer oxide layer (e.g., Fabrication Example), then the saturation current is 600 μA/μm. If a HDP-CVD oxide layer is used as the first interlayer oxide layer (e.g., Comparison 1), then the saturation current is 540 μA/μm. As such, using the HARP oxide layer results in about a 10% increase of the saturation current.

### Evaluation of Erosion Reduction of the Interlayer Oxide Layer

After performing tungsten CMP on the interlayer oxide layer formed according to the Fabrication Example and Comparison 2, an eroded quantity of the interlayer oxide layer as measured. The results are shown in Table 2.

TABLE 2

| | Process Conditions | | |
|---|---|---|---|
| | | Thickness of | Quantity of |
| | Type of | Tungsten | Eroded Oxide |
| | Interlayer Oxide Layer | Layer (Å) | Layer(Å) |
| Fabrication | HARP oxide layer/ | 3000 | 320 |
| Example | TEOS oxide layer | | |
| Comparison 2 | HARP oxide layer | 3000 | 460 |

Referring to Table 2, if a layer exposed by tungsten CMP is the TEOS oxide layer (which is a hard oxide layer), an eroded quantity is decreased by approximately 30% than the HARP oxide layer (which is softer than the TEOS oxide layer). As such, the hard oxide layer is desirable as the layer exposed by tungsten CMP.

According to example embodiments, an interlayer oxide layer is formed as a multiple layer from a first interlayer oxide layer and a second interlayer oxide layer wherein the second interlayer oxide layer is harder than the first interlayer oxide layer. Scratches on the second interlayer oxide layer may decrease when performing CMP on the first interconnect conductive layer. Erosion of the interlayer oxide layer may be more effectively decreased. If the first interlayer oxide layer is formed of a HARP layer, then performance of a transistor increases. If the first interlayer oxide layer is formed of a low dielectric constant film, then parasitic capacitance between gate electrodes decreases.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included within the scope of this invention as defined in the claims. In the claims, means-plus-function clauses are intended to cover the structures described herein as performing the recited function, and not only structural equivalents but also equivalent structures. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims. The present invention is defined by the following claims, with equivalents of the claims to be included therein.

What is claimed is:

1. A semiconductor device, comprising:
gate electrodes formed on a substrate;
a first interlayer oxide layer formed on the substrate and between the gate electrodes;
a second interlayer oxide layer formed on the first interlayer oxide layer, wherein the second interlayer oxide layer is harder than the first interlayer oxide layer; and
a plug electrode formed through the second interlayer oxide layer and the first interlayer oxide layer.

2. The semiconductor device of claim 1, wherein the first interlayer oxide layer is a High Aspect Ratio Process (HARP) oxide layer.

3. The semiconductor device of claim 1, wherein the first interlayer oxide layer is a low dielectric constant film.

4. The semiconductor device of claim 3, wherein the low dielectric constant film is formed of SiOC.

5. The semiconductor device of claim 1, wherein the first interlayer oxide layer is planarized.

6. The semiconductor device of claim 1, wherein the second interlayer oxide layer is formed of a material selected from a group consisting of Tetra Ethyl Ortho Silicate (TEOS), Undoped Silica Glass (USG), Fluorine-doped Silica Glass (FSG) and a combination thereof.

7. The semiconductor device of claim 1, wherein the plug electrode is formed of tungsten.

8. The semiconductor device of claim 1, wherein a portion of the second interlayer oxide layer around the plug electrode resists erosion after chemical-mechanical polishing.

9. The semiconductor device of claim 1, wherein the second interlayer oxide layer is formed of a material having a lower etch rate than the first interlayer oxide layer.

10. The semiconductor device of claim 1, wherein the first interlayer oxide layer is formed of a material that decreases parasitic capacitance between the gate electrodes.

11. A method of fabricating a semiconductor device, comprising:
forming gate electrodes on a substrate;
forming a first interlayer oxide layer on the substrate and between the gate electrodes;
forming a second interlayer oxide layer on the first interlayer oxide layer, wherein the second interlayer oxide layer is harder than the first interlayer oxide layer;
forming a contact hole through the second interlayer oxide layer and the first interlayer oxide layer;
forming a first interconnect conductive layer on the second interlayer oxide layer in the contact hole; and
chemical-mechanical polishing the first interconnect conductive layer to form a plug electrode.

12. The method of claim 11, wherein forming the first interlayer oxide layer includes forming a High Aspect Ratio Process (HARP) oxide layer.

13. The method of claim 11, wherein forming the first interlayer oxide layer includes forming a low dielectric constant film.

14. The method of claim 13, wherein the low dielectric constant film is formed of SiOC.

15. The method of claim 11, further comprising chemical-mechanical polishing the first interlayer oxide layer prior to forming the second interlayer oxide layer.

16. The method of claim 11, wherein the second interlayer oxide layer is formed of a material selected from a group consisting of Tetra Ethyl Ortho Silicate (TEOS), Undoped Silica Glass (USG), Fluorine-doped Silicate Glass (FSG) and a combination thereof.

17. The method of claim 11, wherein the first interconnect conductive layer is formed of tungsten.

18. The method of claim 11, wherein a portion of the second interlayer oxide layer around the plug electrode resists erosion after chemical-mechanical polishing.

19. The method of claim 11, wherein the second interlayer oxide layer is formed of a material having a lower etch rate than the first interlayer oxide layer.

20. The method of claim 11, wherein forming the first interlayer oxide layer is formed of a material that decreases parasitic capacitance between the gate electrodes.
